(19) United States
(12) Patent Application Publication
(10) Pub. No.: US 2014/0159840 A1
(43) Pub. Date: Jun. 12, 2014

(54) MAGENTIC MOBILE DEVICE HOLDER

(71) Applicant: Asma Moin Qadri, Edmonton (CA)

(72) Inventor: Asma Moin Qadri, Edmonton (CA)

(21) Appl. No.: 13/712,959

(22) Filed: Dec. 12, 2012

(51) Int. Cl. H05K 5/02

(52) U.S. Cl. CPC H05K 5/02
USPC 335/285

(57) ABSTRACT

An apparatus for securing a mobile device to a user comprises at least one connector for connection to a user, a retaining body having a magnet located therein suspended from the connector and a ferromagnetic body securable to at least one surface of the mobile communication device, wherein the ferromagnetic body is magnetically attractable to the magnet. A method for securing a mobile device to a user comprises securing a ferromagnetic plate to at least one surface of the mobile communication device, securing a connector to a user and attaching the ferromagnetic plate to a magnet located within a retaining body suspended from the connector.

### BACKGROUND OF THE INVENTION

1. Field of Invention

The present invention relates to mobile devices in general and in particular to the method and apparatus for securing a mobile communication device to a user.

2. Description of Related Art

Cellular phones and other mobile communication devices are an increasingly common device for many people. Such devices assist with many aspects of daily life from business to social communications as well as the rapid and efficient dissemination of information. Examples of such include cellular phones, smart phones, personal digital assistants (“PDAs”) and tablet computers.

As many people are beginning to carry such mobile communication devices, the need has arisen to provide an efficient and convenient manner to carry such devices by the user at a wide variety of times or locations. Many previous manners to of carrying such devices have been previously attempted. However such attempts have been limited in their ease of operation, adaptability to other devices or may otherwise depend upon specific articles of clothing for their proper implementation.

In particular, some carrying devices have provided a clip or other body capable of securing to a belt of the user. Such device however are dependent upon the user wearing a belt to be secured to. Such devices have also commonly been adapted to secure to and retain a specific model of mobile communication device therein and have therefore been limited to those devices having the required shape. Many of such devices also include specific connector which may only be engaged with protrusions of the desired mobile communication device. Examples of such device may be found in U.S. Pat. No. 6,135,408 to Richter.

### SUMMARY OF THE INVENTION

According to a first embodiment of the present invention there is disclosed an apparatus for securing a mobile device to a user comprising at least one connector for connection to a user, a retaining body having a magnet located therein suspended from the connector and a ferromagnetic body securable to at least one surface of the mobile communication device, wherein the ferromagnetic body is magnetically attractable to the magnet.

The ferromagnetic body may comprise a substantially planar body. The ferromagnetic body may comprise a plate. The ferromagnetic body may be formed of steel. The ferromagnetic body may be secured to the mobile communication device with adhesives.

The retaining body may include an outer shell. The outer shell may be formed of at least one sheet of material adapted to overlay the magnet. The shell may be formed of a material selected from the group consisting of plastic, nylon, rubber, silicon, fabric or composite materials. The shell may substantially surround the magnet. The shell may comprise first and second substantially planar bodies located on opposed sides of the magnet. The shell may have an outer surface corresponding to the ferromagnetic body.

The connector may extend from the shell. The connector may comprise a pin securable to an article of clothing of the user. The connector may comprise a lanyard. The connector may comprise a pocket formed in an article of clothing. The magnet may comprise a rare earth magnet. The magnet may comprise a neodymium magnet.

According to a further embodiment of the present invention there is disclosed a method for securing a mobile device to a user comprising securing a ferromagnetic plate to at least one surface of the mobile communication device, securing a connector to a user and attaching the ferromagnetic plate to a magnet located within a retaining body suspended from the connector.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention wherein similar characters of reference denote corresponding parts in each view,

FIG. 1 is a rear perspective view of an apparatus for holding a mobile communication device according to a first embodiment of the present invention.

FIG. 2 is a cross-sectional view of the apparatus of FIG. 1 being located below a user's article of clothing and having the mobile communication device being applied to an as taken along the line 2-2.

FIG. 3 is a cross-sectional view of the apparatus of FIG. 1 according to a further embodiment of the present invention having a pin connector and a split shell.

FIG. 4 is a cross-sectional view of the apparatus of FIG. 1 according to a further embodiment of the present invention having a pin connector located to a rear thereof.

FIG. 5 is a cross-sectional view of the apparatus of FIG. 1 according to a further embodiment of the present invention having a pocket attached to a user's clothing.

FIG. 6 is a front view of a user having a mobile communication device attached to their shirt by the apparatus of FIG. 1.

### DETAILED DESCRIPTION

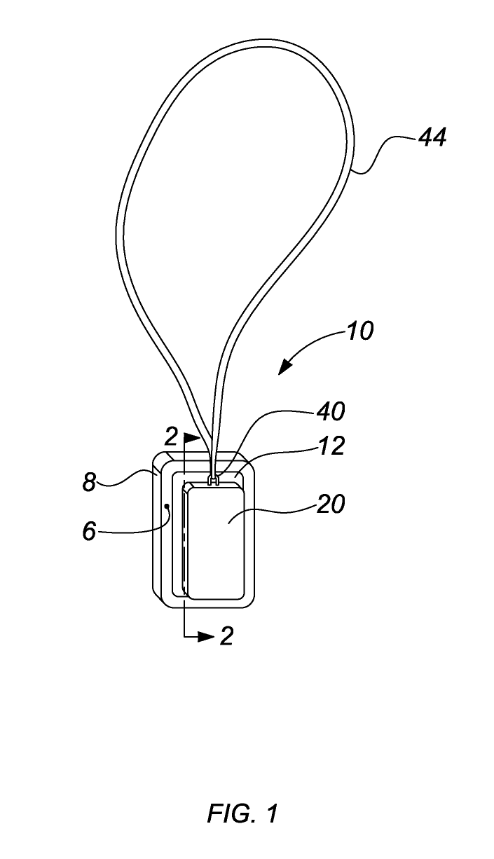

Referring to FIG. 1, an apparatus for holding a mobile communication device according to a first embodiment of the invention is shown generally at 10. The apparatus comprises a ferromagnetic body 12 securable to at least one surface of the mobile communication device 8 and a retaining body 20 having a magnet located therein and at least one connector for flexibly supporting said retaining body from the user. The mobile communication device 8 may be of any commonly known type, such as, by way of non-limiting example, cellular phones, PDAs, tablet computers or smart phones and other media devices, such as mp3 players. As illustrated in FIGS. 1 through 3, the ferromagnetic body 12 may be secured to a rear surface 6 of the mobile communication device 8 although it will be appreciated that the ferromagnetic body 12 may be secured to other surfaces of the mobile communication device as well.

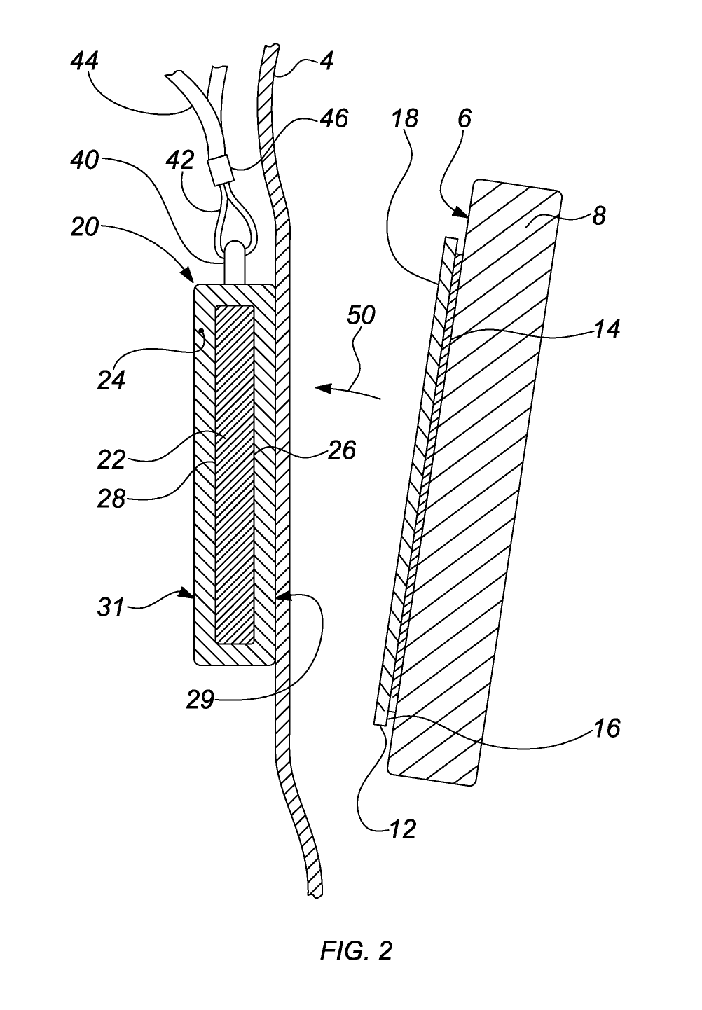

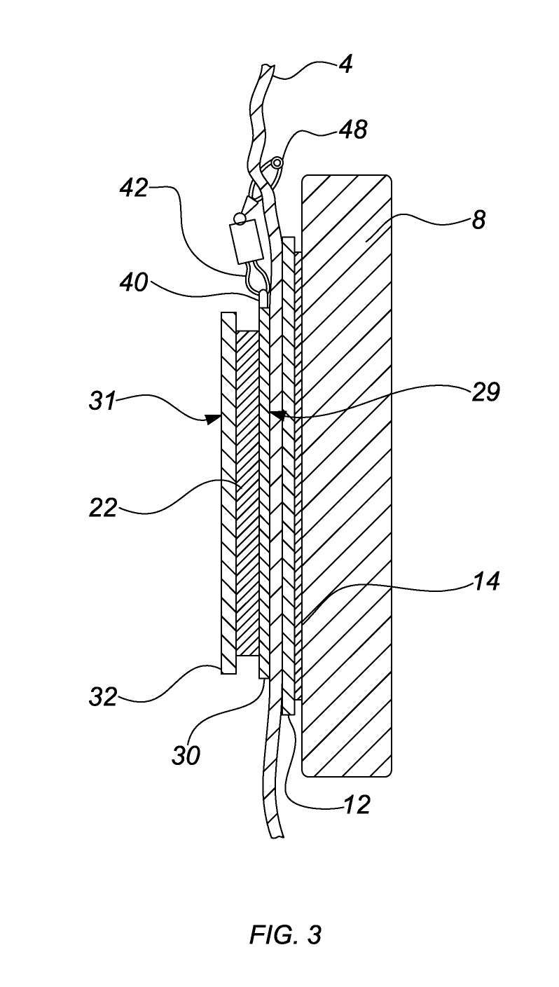

As illustrated in FIGS. 2 and 3, the ferromagnetic body 12 is secured to the rear surface 6 of the mobile communication device 8 by any commonly known means, such as, by way of non-limiting example, adhesives, tape or the like. In particular, it has been found that double sided tape 14, such as, Command Brand strips™ manufactured by 3M™, by way of non-limiting example may be particularly useful.

As illustrated in FIG. 1, the ferromagnetic body 12 may comprise a substantially planar sheet of a ferromagnetic metal having front and rear surfaces, 16 and 18, respectively. The front surface 16 of the ferromagnetic body 12 may be secured to the mobile communication device 8 with the double sided tape 14 while the rear surface 18 is oriented away from the mobile communication device 8. The rear surface 18 is substantially flat and unobstructed so as to permit a smooth coupling with the retaining body 20 as will be more fully described below. Optionally, the ferromagnetic body 12 may be incorporated into or built into the mobile communication device 8.

The ferromagnetic body may be formed of any suitable ferromagnetic material, such as, by way of non-limiting example, iron, steel and alloys thereof. The ferromagnetic body may have a thickness selected to provide a sufficient magnetic attraction to a magnet, while being light enough to not significantly add to the weight of the mobile communication device 8. In practice, it has been found that a thickness of between 0.0004 and 0.06 inches (0.01 and 1.4 mm) have been useful although it will be appreciated that other thicknesses may be useful as well. The ferromagnetic body 12 may also have an outline of sufficient size to provide an adequate mounting surface as described below. In practice, it has been found that an outline of less than the outer dimension of the mobile communication device 8 prevents the ferromagnetic body from significantly adding to the size of the mobile communication device 8. It will be appreciated that the ferromagnetic body 12 may have any suitable outline shape, such as, by way of non-limiting example, rectangular, square, oval, circular, triangular, octagonal, or irregular as may be desired by an end user. The ferromagnetic body 12 may also optionally be painted or coated to provide a pleasing aesthetic appearance.

The retaining body 20 comprises a magnetic core 22 surrounded by a shell 24. The magnetic core 22 may be of any suitable shape and includes substantially planar front and rear surfaces, 26 and 28, respectively. The magnetic core 22 may be formed of any suitable permanent magnet, such as by way of non-limiting example, magnetized iron cores and rare earth magnets, such as samarium-cobalt and neodymium magnets. The magnetic core may be selected to provide a sufficient magnetic attraction to attract and retain the ferromagnetic body proximate thereto. In practice it has been found that a neodymium magnet having a magnetic field strength of between 2000 and 30,000 gauss may be useful although it will be appreciated that other strengths may be useful as well. The magnetic core may also have a magnetization direction that can be either axial or diametrical. It will also be appreciated that the magnetic core 22 may be formed of one or more magnets located within the retaining body.

As illustrated in FIG. 2, the shell 24 may comprise a layer of material surrounding the magnetic core 22. The shell 24 may be formed around the magnetic core 22 by any suitable means, such as, by way of non-limiting example, injection molding, painting, casting or by forming one or more interconnection elements which are operable to be connected together to form the completed shell 24. The shell has front and rear surfaces, 29 and 31, respectively which are substantially planar and flat. Optionally, the shell 24 may comprise front and rear panels, 30 and 32, respectively located adjacent to the front and rear surfaces 26 and 28 of the magnetic core 22. In such embodiments, the front and rear panels 30 and 32 may be secured to the magnetic core by any suitable means, such as, by way of non-limiting example adhesives, or the like. The shell protects the magnetic core 22 from impacts contact with a user and may be formed of any suitable non-magnetic material, such as, by way of non-limiting example plastic, natural or synthetic rubbers, silicone, fabrics or composite materials. It will also be appreciated that the shell 24 may be formed of one or more layers of the same or different materials.

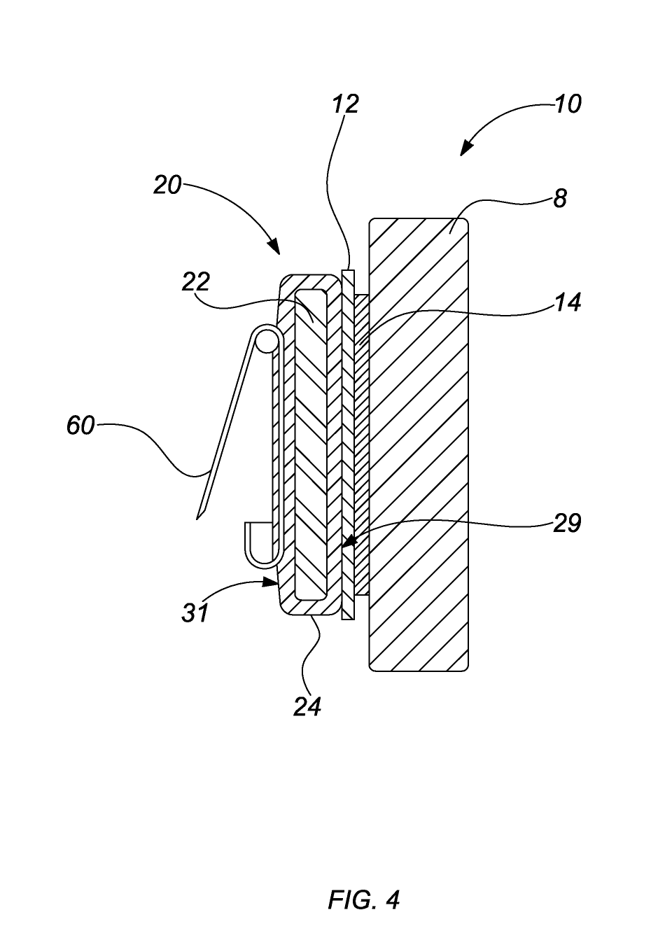

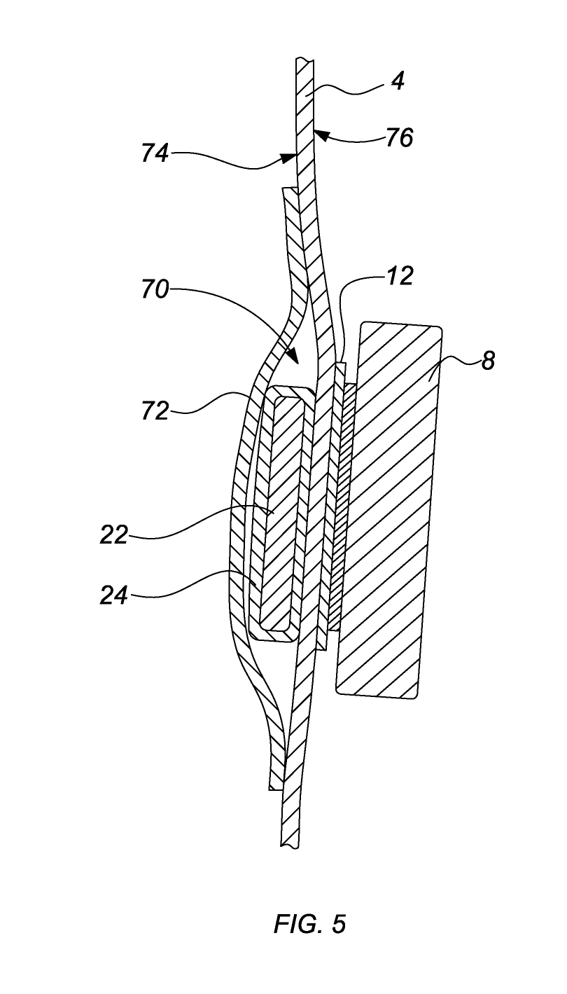

With reference to FIG. 2, the shell 24 includes a loop 40 extending therefrom. The loop 40 provides a connection point for a string 42 or the like to be passed therethrough. As illustrated in FIG. 2, the string 42 extends between the loop 40 and a lanyard 44 which may be passed around a user's neck or the like. The string 42 and lanyard 44 may be secured to each other by any suitable means such a commonly formed junction block 46 as is commonly known. It will also be appreciated that other flexible members, such as, flexible coils, ropes or strings may be utilized in place of the lanyard. Optionally, as illustrated in FIG. 3, the string 42 may extend to a pin 48 as is commonly known which may be secured to a user's article of clothing so as to suspend the apparatus 10 therefrom. Optionally, the a pin 60 may be embedded into a surface, such as, by way of non-limiting example, the rear surface 31 of the shell 24 as illustrated in FIG. 4. It will also be appreciated that one or more of the above connectors may be utilized with a common retaining body 20. It will also be appreciated that although pins and lanyards are illustrated and described above, other connector types, such as, by way of non-limiting example, hooks, clasps or clips may also be utilized to provide a flexible connection between the user and the retaining body while permitting a degree of movement. As illustrated in FIG. 5, the connector may also optionally comprise a pocket 70 formed by a sheet of fabric 72 sewn or otherwise adhered to either an inside or outside surface, 74 or 76, respectively of a user's article of clothing 4. By way of non-limiting example, the article of clothing may comprise a shirt, shorts, pants, coat or any other clothing as desired by a user.

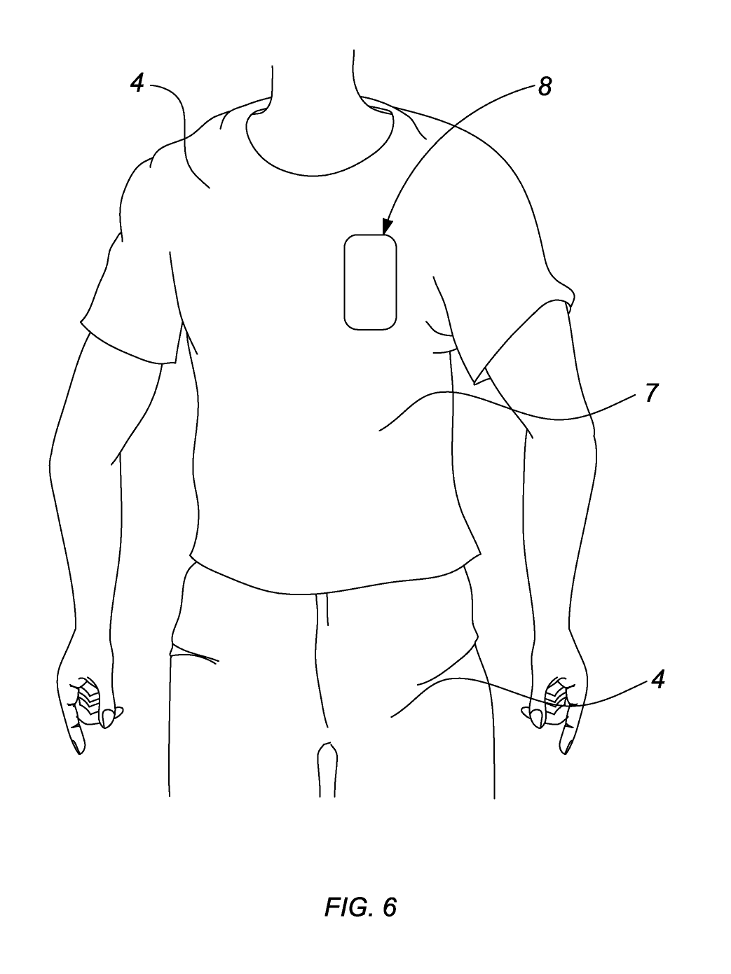

In operation, a user may locate the retaining body 20 below their clothing by passing the lanyard 44 over their neck or securing the pin 48 to an article of their clothing 4. In such a manner, the retaining body 20 will be suspended from user with a degree of freedom of movement. In particular, it will be observed that the user may position the retaining body 20 at any desired position or orientation. Additionally, the user may rotate or otherwise turn the retaining body 20 so as to orient the mobile communication device 8 to any desired orientation. Thereafter, the user may move the mobile communication device 8 in a direction generally indicated at 50 towards the retaining body 20 so as to bring the ferromagnetic body 12 into the magnetic attraction range of the magnetic core 22. Thereafter the magnetic core 22 will attract the ferromagnetic body 12 theretowards so as to engage the ferromagnetic body 12 with the magnetic core 22. As illustrated in FIGS. 2 and 3, the retaining body 20 and the ferromagnetic body 12 may be coupled together with a portion of fabric 4 of a user's clothing located therebetween. In such a way, the user may position the retaining body 20 under their clothing such that when they desired to hold their mobile communication device 8, they may place the mobile communication device 8 proximate to the location of the retaining body so as to engage the ferromagnetic body 12 thereon such that the magnetic attraction between the ferromagnetic body 12 and the magnetic core 22 would retain the mobile communication device 8 in the desired location. By way of non-limiting example, as illustrated in FIG. 6 an apparatus according to the present disclosure may be operable to retain a mobile communication device against the front of a shirt 7 of a user. It will be appreciated that other locations and clothing articles may be used with the present apparatus as well.

As set out above, the front and rear surfaces 29 and 31 of the retaining body are substantially flat and planar so as to correspond to the rear surface 18 of the ferromagnetic body 12. In such a way, the fabric 4 of the user's clothing will not be marked or otherwise damaged by any protrusions from either surface. It will also be observed that as both of the front and rear surfaces are substantially flat, the retaining body 20 may be rotated so as to be coupled to the ferromagnetic body 12 by either surface.

While specific embodiments of the invention have been described and illustrated, such embodiments should be considered illustrative of the invention only and not as limiting the invention as construed in accordance with the accompanying claims.

What is claimed is:

1. An apparatus for securing a mobile device to a user comprising:
at least one connector for connection to a user;
a retaining body having a magnet located therein suspended from said connector; and
a ferromagnetic body securable to at least one surface of said mobile communication device, wherein said ferromagnetic body is magnetically attractable to said magnet.

2. The apparatus of claim 1 wherein said ferromagnetic body comprises a substantially planar body.

3. The apparatus of claim 2 wherein said ferromagnetic body comprises a plate.

4. The apparatus of claim 1 wherein said ferromagnetic body is formed of steel.

5. The apparatus of claim 1 wherein said ferromagnetic body is secured to said mobile communication device with adhesives.

6. The apparatus of claim 1 wherein said retaining body includes an outer shell.

7. The apparatus of claim 6 wherein said outer shell is formed of at least one sheet of material adapted to overlay said magnet.

8. The apparatus of claim 7 wherein said shell is formed of a material selected from the group consisting of plastic, nylon, rubber, silicon, fabric or composite materials.

9. The apparatus of claim 7 wherein said shell substantially surrounds said magnet.

10. The apparatus of claim 7 wherein said shell comprises first and second substantially planar bodies located on opposed sides of said magnet.

11. The apparatus of claim 6 wherein said shell has an outer surface corresponding to said ferromagnetic body.

12. The apparatus of claim 6 wherein said connector extends from said shell.

13. The apparatus of claim 12 wherein said connector comprises a pin securable to an article of clothing of said user.

14. The apparatus of claim 12 wherein said connector comprises a lanyard.

15. The apparatus of claim 1 wherein said connector comprises a pocket formed in an article of clothing.

16. The apparatus of claim 1 wherein said magnet comprises a rare earth magnet.

17. The apparatus of claim 16 wherein said magnet comprises a neodymium magnet.

18. A method for securing a mobile device to a user comprising:
securing a ferromagnetic plate to at least one surface of said mobile communication device;
securing a connector to a user; and
attaching said ferromagnetic plate to a magnet located within a retaining body suspended from said connector.
